(19) United States
(12) Patent Application Publication
(10) Pub. No.: US 2023/0099138 A1
(43) Pub. Date: Mar. 30, 2023

(54) SEEBECK DEVICE IN A LASER SYSTEM

(71) Applicant: Applied Research Associates, Inc., Albuquerque, NM (US)

(72) Inventors: Joseph N. Paranto, Albuquerque, NM (US); Aaron Majdali, Albuquerque, NM (US)

(21) Appl. No.: 17/955,130

(22) Filed: Sep. 28, 2022

Related U.S. Application Data
(60) Provisional application No. 63/249,766, filed on Sep. 29, 2021.

(51) Int. Cl. H01S 5/024

(52) U.S. Cl. CPC H01S 5/02415; H01S 5/02423; H01S 5/02476

(57) ABSTRACT

A thermoelectric device and method of use thereof are provided for cooling and powering a laser device. The thermoelectric device comprises a first side, a second side, and a plurality of thermoelectric elements disposed therebetween. The thermoelectric device engages a photodiode array of the laser device, such that when heat is generated by the photodiode array, the thermoelectric device passively cools the photodiode array by receiving the heat and converts the heat generated to electricity to power the laser device.

### RELATED APPLICATIONS

This application claims priority benefit of U.S. Provisional Patent Application No. 63/249,766, filed Sep. 29, 2021, and entitled “SEEBACK DEVICE IN A LASER SYSTEM,” which is herein incorporated by reference in its entirety.

### BACKGROUND

### 1. Field

Embodiments of the invention relate to cooling and powering a laser system. More specifically, embodiments of the invention relate to one or more thermoelectric devices operatively connected to a laser system.

### 2. Related Art

A significant problem in laser systems is heat generation from a photodiode array and requisite cooling of said photodiode array. Typically, this problem is resolved by active cooling of the photodiode array using a type of liquid or air-cooling channel. Such cooling processes require energy from the system to actively cool the photodiode array. Additionally, some laser systems may require a duration of time in between use to allow for the temperature of the photodiode array to cool to a predetermined level. Furthermore, these systems do not take advantage of thermoelectric energy that may be harnessed to augment the laser system.

### SUMMARY

Embodiments of the invention solve the above-mentioned problems by providing a system, method, and device for cooling and powering a laser device. In some embodiments, the system comprises a thermoelectric device to feedback power to the laser device while additionally cooling the laser device.

In some aspects, the techniques described herein relate to a power generation and cooling system for a laser device, the system including: one or more thermoelectric devices, each defining a first side and a second side, wherein the first side engages a photodiode array of the laser device and configured to receive heat therefrom, wherein the second side operatively engages a cooling element of the laser device; a plurality of thermoelectric elements disposed between the first side and the second side; and a power connection, wherein said power connection electrically connects the one or more thermoelectric devices and the laser device.

In some aspects, the techniques described herein relate to a power generation and cooling system for a laser device, the system including: at least one heat sink engaging a photodiode array of the laser device; one or more thermoelectric devices, each defining a first side and a second side having a plurality of thermoelectric elements disposed therebetween, wherein the first side of each of the one or more thermoelectric devices engages the at least one heat sink and receives heat therefrom; and a power connection electrically coupling the one or more thermoelectric devices to the laser device.

In some aspects, the techniques described herein relate to a method for cooling and powering a laser device, the method including: activating the laser device, wherein activation of the laser device generates heat at a photodiode array of the laser device; receiving the heat generated by the photodiode array at a first side of a thermoelectric device; generating electricity at the thermoelectric device via the heat received at the first side; and powering the laser device via the electricity generated from the thermoelectric device.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the invention will be apparent from the following detailed description of the embodiments and the accompanying drawing figures.

### BRIEF DESCRIPTION OF THE DRAWING FIGURES

Embodiments of the invention are described in detail below with reference to the attached drawing figures, wherein:

FIG. 1 shows a cross-sectional view of a laser device having a thermoelectric device relating to some embodiments of the invention;

FIG. 2 shows a cross-sectional view of some embodiments of a power generation and cooling system for the laser device of FIG. 1;

FIG. 3 shows a cross-sectional view of some embodiments of a power generation and cooling system for the laser device of FIG. 1;

FIG. 4 shows a method for cooling and powering a laser device relating to some embodiments of the invention; and

FIG. 5 shows a method for manufacturing a thermoelectric device operatively engaging a photodiode array relating to some embodiments of the invention.

The drawing figures do not limit the invention to the specific embodiments disclosed and described herein. The drawings are not necessarily to scale, emphasis instead being placed upon clearly illustrating the principles of the invention.

### DETAILED DESCRIPTION

The following detailed description references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the invention. The following detailed description is, therefore, not to be taken in a limiting sense. The scope of the invention is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the technology can include a variety of combinations and/or integrations of the embodiments described herein.

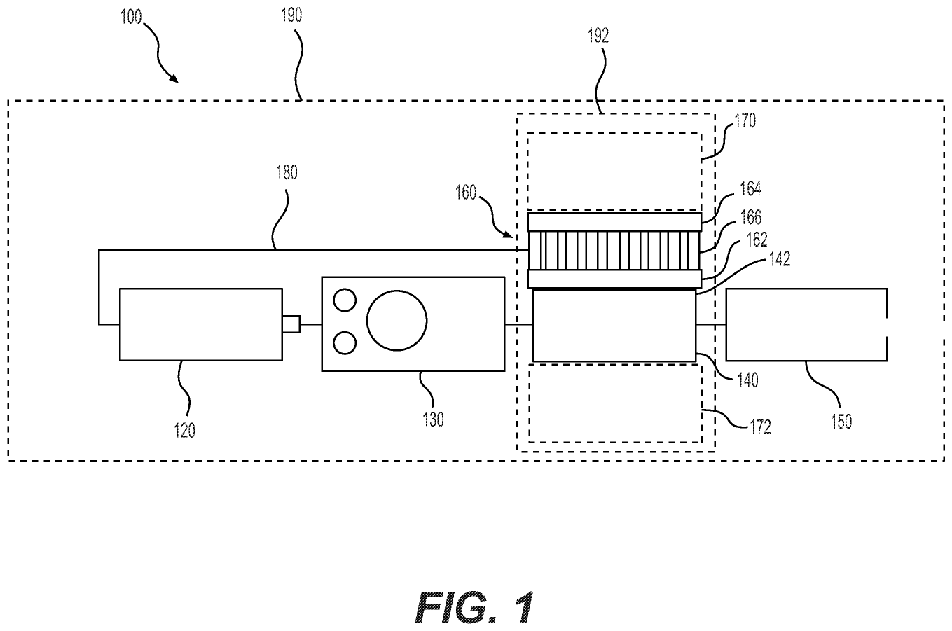

Turning first to FIG. 1, a cross-sectional view of a laser device 100 is depicted relating to some embodiments. In such embodiments, the laser device 100 comprises a battery 120, a power supply 130, a photodiode array 140, a plurality of laser fibers 150, and a thermoelectric (TE) device 160. The TE device 160 includes a first side 162, a second side 164, and a plurality of thermoelectric components 166 therebetween. In some embodiments, the first side 162 of the TE device 160 is disposed adjacent to the photodiode array 140. For example, the first side 162 may be directly contacting a portion of the photodiode array 140. Alternatively, in some embodiments, the photodiode array 140 may be disposed entirely within the TE device 160, such that the first side 162 may mechanically engage the photodiode array 140 in its entirety. In this case, the photodiode array 140 may be in a rectangular or circular shape.

In some embodiments, a thermally conductive material 142 may be disposed between the first side 162 of the TE device 160 and the photodiode array 140 to efficiently transfer the heat generated by the photodiode array 140 to the first side 162 of the TE device 160. This thermally conductive material 142 may comprise a liquid, a solid, or a combination of a liquid and a solid. In one example, the thermally conductive material 142 may comprise one or more of water, deionized water, inhibited glycol solutions, or dielectric liquids. In one example, the thermally conductive material 142 may comprise one or more of diamond, silver, copper, gold, silicon carbide, beryllium oxide, aluminum, tungsten, graphite, or zinc.

In some embodiments, the first side 162 and the second side 164 of the TE device 160 comprise one or more of silicon, a ceramic, or a polymer. In one example, the first side 162 or the second side 164 may comprise alumina. However, embodiments are contemplated in which a variety of different materials may be included.

In some embodiments, the thermoelectric components 166 may comprise one or more elements. For example, the thermoelectric components 166 may comprise one or more of polycrystalline silicon, silver, nickel, copper, bismuth telluride, lead, beta-zinc antimonide, or calcium manganese oxide, as well as other materials not described herein. In another example, the thermoelectric components 166 may comprise an alloy of one or more of silver, nickel, or copper.

In some embodiments, the thermoelectric components 166 may be operatively connected to the first side 162 and the second side 164. In one example, the thermoelectric components 166 may be operatively connected to the first side 162 and the second side 164 via soldering, wherein the solder material may comprise of a metal. In one example, the thermoelectric components 166 may be operatively connected to the first side 162 and the second side 164 via soldering using one or more of aluminum, copper, or another suitable soldering metal.

The thermoelectric components 166 may be operatively connected to the first side 162 and the second side 164 via physical mounting. Alternatively, in one embodiment, the thermoelectric components 166 may be operatively connected to the first side 162 and the second side 164 via polishing.

In some embodiments, the thermoelectric components 166 may be arranged in different configurations. In one example, e.g., as shown in FIG. 1, the thermoelectric components 166 may be arranged in a conventional configuration. In this example, both ends of the thermoelectric components 166 are operatively coupled to the first side 162 and the second side 164 of the TE device 160. In one example, the thermoelectric components may be arranged in a segmented configuration (not shown). In this example, two or more thermoelectric components 166 are disposed in a vertical configuration between the first side 162 and the second side 164 of the TE device 160 (not shown). In this example, the two or more thermoelectric components 166 may comprise the same or different materials, as described above.

In some embodiments, the TE device 160 may comprise multiple TE devices 160 arranged in a plurality of different configurations. For example, a configuration of the TE devices 160 may be a planar configuration, comprising one layer of TE devices 160 disposed adjacent to the photodiode array 140. In one example (not shown), a configuration may be a cascaded configuration, comprising multiple TE devices 160 stacked vertically. In this example, the stacking of TE devices (e.g., like TE device 160) may comprise the first side 162 of a second TE device 160 disposed adjacent to the second side 164 of a first TE device 160. In this sort of configuration, the TE devices 160 stack outwardly from the photodiode array 140. In one example, the TE devices 160 may be arranged in a mixed configuration (not shown). In said mixed configuration, the TE devices 160 are disposed in a lateral position adjacent to the photodiode array 140 such that the first side 162 and the second side 164 extend perpendicular from the photodiode array 140.

In some embodiments, the second side 164 of the TE device 160 may be disposed adjacent to a first cooling channel 170. The first cooling channel 170 may effectively cool the second side 164 to generate a greater difference in temperature between the first side 162 and second side 164. By increasing the difference in temperatures between the first side 162 and second side 164, the TE device 160 may generate more electrical power to further power the laser device 100.

Similarly, in some embodiments, a second cooling channel 172 may be disposed on a side of the photodiode array 140. For example, second cooling channel 172 may be disposed adjacent to the photodiode array 140 on the opposing side to TE device 160. In such a configuration, second cooling channel 172 helps directly cool photodiode array 140 while still allowing heat from the other side of photodiode array 140 to heat first side 162 of TE device 160 and thereby generate power. As such, second cooling channel 172 may prevent overheating of photodiode array 140.

In some embodiments, the first and second cooling channels 170, 172 may comprise an outer portion defining a cavity wherein a coolant may be housed. In one example, the coolant may flow through said cavity by pneumatic forces. In one example, the coolant may flow through said cavity by electrically actuated motors. In one example, the coolant may flow through said cavity by capillary action.

The coolant may comprise different elements which effectively transfer heat. For example, the coolant may comprise water. In one example, the coolant may comprise propanol. In one example, the coolant may comprise alcohol. In one example, the coolant may comprise freon.

In some embodiments, the TE device 160 is electrically connected to the battery 120 via a power connection 180. In some embodiments, the TE device 160 is operatively connected to power supply 130 via power connection 180 (not shown). In some embodiments, the TE device 160 is electrically connected to battery 120 and power supply 130 via power connection 180 (not shown). Power connection 180 may comprise electrical components for efficient transfer of electricity generated by the TE device 160. Furthermore, power connection 180 may be insulated so as to prevent, or substantially decrease, heat released from power connection 180.

In some embodiments, the devices of the laser device 100 may be encased in a laser enclosing 190. The laser enclosing 190 may comprise an insulating material to insulate the laser device 100 from the outside air temperature. The insulating material of the laser enclosing 190 may comprise one or more of ceramic, plastic, metal, or rubber.

In some embodiments, the photodiode array 140, TE device 160, and cooling channel 170 may be encased in a thermal insulator 192. The thermal insulator 192 may comprise an insulating material to insulate the photodiode array 140, TE device 160, and cooling channel 170 from varying temperatures of other devices within the laser device 100. The insulating material of the thermal insulator 192 may comprise one or more of ceramic, plastic, metal, or rubber.

In some embodiments, one or more TE devices (e.g., TE device 160) are integrated directly into the photodiode array 140. For example, photodiode array 140 may be developed such that one or more TE devices 160 are disposed on internal or external components of photodiode array 140. Similar to the description above, in these embodiments first side 162 may be disposed close to, or in contact with, a portion or component of photodiode array 140 that exhibits an increase in temperature while in use. Further, second side 164 may be disposed such that it is a distance away from the portion or component of photodiode array 140 exhibiting the increased temperature. In this way, the one or more TE devices 160 integrated into photodiode array 140 are able to simultaneously absorb some heat and prevent overheating while also providing power back to the system (e.g., by charging battery 120 or power supply 130).

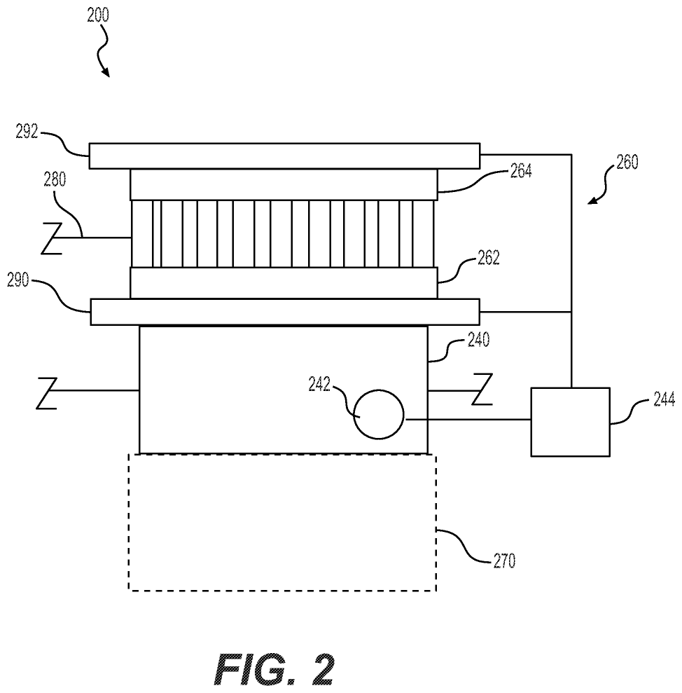

FIG. 2 depicts some embodiments of configurations of a power generation and cooling system 200 disposed within a laser device (e.g., laser device 100), with some components of the laser device hidden for clarity. Power generation and cooling system 200 may include a photodiode array 240, a TE device 260, a first microchannel plate 290, a second microchannel plate 292, a controller 244, a temperature probe 242, and a secondary cooling channel 270. In these embodiments, one or more microchannel plates (e.g., first microchannel plate 290 and second microchannel plate 292) may be used to specifically cool certain components. Microchannel plates pass a coolant, passively or actively, through a plurality of enclosed channels disposed within the plate. In embodiments, the coolant passing through first and second microchannel plates 290, 292, may be one or more of water, propanol, alcohol, or freon. Passage of the coolant through the plurality of channels may act to wick away heat from an object disposed against or next to the microchannel plate. For example, as depicted, first microchannel plate 290 may cool a portion of photodiode array 240 and/or first side 262 of TE device 260. Similarly, second microchannel plate 292 may cool second side 264 of TE device 260. First and second microchannel plates 290, 292, may be fluidly coupled a coolant source, such as a coolant basin. Furthermore, coolant movement within first and second microchannel plates 290, 292, may be caused by one or more of pneumatic forces, electrically actuated motors, or capillary action.

In some embodiments, first microchannel plate 290 and second microchannel plate 292 may include one or more valves that regulate the flow of the coolant through the microchannels. The valves may be regulated by a controller (e.g., controller 244). For example, valves disposed within first microchannel plate 290 may be closed to allow for heat transfer from photodiode array 240, through first microchannel plate 290, to first side 262 of TE device 260. Such transfer of heat may increase the power output of TE device 260 by increasing the temperature difference between first side 262 and second side 264. Furthermore, valves disposed within second microchannel plate 292 may be open most or all of the time, thereby decreasing the temperature of second side 264 and thus further increase the temperature differential between first side 262 and second side 264.

As mentioned previously, in embodiments in which first and second microchannel plates 290, 292, include regulatable valves, a controller 244 may be configured to command the opening and closing of the valves. In some embodiments, controller 244 may receive temperature feedback from one or more components of the laser device 100. For example, in some embodiments temperature probe 242 may measure the temperature of photodiode array 240. Thermal data may be interpreted, relayed, or otherwise communicated to controller 244 from temperature probe 242. Controller 244 then may, using the thermal data, determine whether or not to open one or more valves disposed within first and second microchannel plates 290, 292 for cooling purposes. For exemplary purposes, controller 244 may determine, via thermal data received from temperature probe 242, that photodiode array 240 has exceeded a predetermined high temperature threshold. Accordingly, the controller may command one or more valves disposed within first microchannel plate 290 open. Controller 244 may then receive thermal data from temperature probe 242, continuously or at a predetermined rate, to determine when the temperature of the photodiode array 240 is below a predetermined low temperature threshold. In some embodiments, once controller 244 determines that photodiode array 240 is below the predetermined low temperature threshold, controller 244 may command one or more valves disposed in first microchannel plate 290 closed to aid in heat transfer from the photodiode array 240 to the TE device 260.

In some embodiments, it is envisioned that a secondary cooling channel 270 may be disposed against or near photodiode array 240 to aid in thermal transfer away from photodiode array 240. In some embodiments, secondary cooling channel 270 may be disposed opposite the TE device 260 about photodiode array 240. Such a configuration would aid in cooling photodiode array 240, while still allowing heat transfer on the opposite side to pass to the TE device 260 for generating power.

In some embodiments, the configuration of the depicted cooling system 200 may be adjusted to enhance power generation. For example, as discussed above there may be more than one TE device 260 disposed on photodiode array 240. Additionally, there may be more than one TE device 260 stacked on top of one another. For example, within power generation and cooling system 200, a second TE device (not shown) may be stacked on top of second microchannel plate 292. Further, a third microchannel plate (not shown) may be stacked on top of the second TE device. In these embodiments, controller 244 may be communicatively coupled to each microchannel plate. Additionally, there may be more than one thermal probe that communicates the temperature of TE device 260 and the second TE device to controller 244. Accordingly, controller 244 may command valves in all microchannels simultaneously to regulate the temperature and output of the TE devices.

In some embodiments, valve actuation within the first and second microchannel plates 290, 292, may be that of a passive nature. For example, in some embodiments power generation and cooling system may lack controller 244. Rather, valves within the first and second microchannel plates 290, 292, may be configured to open at a certain temperature or pressure.

In some embodiments, controller 244 may be communicatively coupled to a voltage or current meter (not shown) that measures output from TE device 260. For example, voltage at power connection 280 may be relayed to controller 244. Voltage output from TE device 260 may be used to determine when and which valves in first and second microchannel plates 290, 292, to open and/or close. For example, in a scenario in which voltage output from TE device 260 is low but temperature of photodiode array 240 is high, controller 244 may command more valves within first microchannel plate 290 to a closed configuration so as to enhance heat transfer from photodiode array 240, through first microchannel plate 290, to first side 262 of TE device 260. Such an example is not meant to be construed as limiting, as one of skill in the art could envision many scenarios in which controller 244, using voltage/current information from power connection 280 as well as temperature information from photodiode array 240, may regulate cooling of photodiode array 240 and TE device 260 via valves disposed within first and second microchannel plates 290, 292.

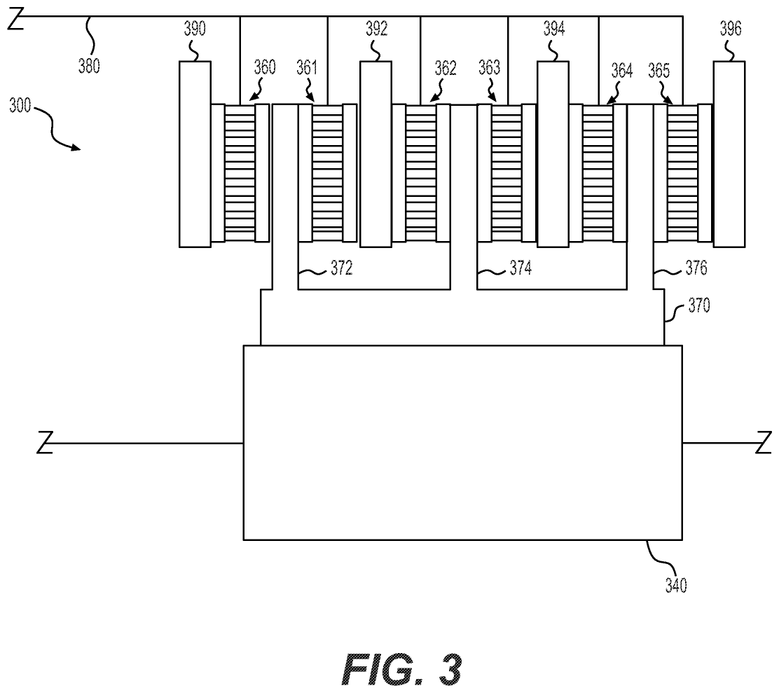

FIG. 3 depicts some embodiments of configurations of a power generation and cooling system 300 disposed within a laser device (e.g., laser device 100), with some components of the laser device hidden for clarity. In some embodiments, power generation and cooling system 300 may include a heat sink 370 disposed on or adjacent to photodiode array 340. Heat sink 370 may comprise any material that effectively absorbs and radiates heat away from the heat source (e.g., photodiode array 340). As depicted, heat sink 370 may comprise one or more fins. For exemplary purposes, heat sink 370 is depicted having a first fin 372, second fin 374, and third fin 376. However, it is to be understood that heat sink 370 may include any number of fins and any configuration of fins.

As shown in FIG. 3, power generation and cooling system 300 may include multiple TE devices. For example, power generation and cooling system 300 may include a first TE device 360, a second TE device 361, a third TE device 362, a fourth TE device 363, a fifth TE device 364, and a sixth TE device 365. However, it is to be understood that power generation and cooling system 300 may include any number of TE devices. For example, there may be a pair of TE devices disposed on each fin of the heat sink 370 (as depicted in FIG. 3). In another example, there may be a TE device disposed on every other fin of the heat sink 370. In yet another example, there may be a TE device disposed on the outer fins located on the heat sink 370.

In some embodiments, power generation and cooling system 300 includes one or more cooling channels disposed adjacent to the TE devices. For example, power generation and cooling system 300 may include a first cooling channel 390, a second cooling channel 392, a third cooling channel 394, and a fourth cooling channel 396. However, it is to be understood that power generation and cooling system 300 may comprise any number of cooling channels. In some embodiments, power generation and cooling system 300 includes as many cooling channels as TE devices. In some embodiments, power generation and cooling system 300 includes more cooling channels than TE devices. In some embodiments, power generation and cooling system 300 includes fewer cooling channels than TE devices (as depicted in FIG. 3). Similar to first and second cooling channels 170, 172, cooling channels of power generation and cooling system 300 may include a coolant that effectively transfers heat, such as water, propanol, alcohol, or freon. Additionally, cooling channels of power generation and cooling system 300 may actively or passively move coolant therein, such as via pneumatic forces, electrically actuated motors, or capillary action. Not shown here, first, second, third, and fourth cooling channels 390, 392, 394, and 396, may be fluidly coupled to one coolant basin or respective coolant basins, whereby the basins act as a source of coolant.

In some embodiments, the configuration of the cooling channels and TE devices is such that the cooling channel may decrease the temperature of the side of the TE device opposite the side of the TE device that is disposed against the heat sink. For example, first cooling channel 390 is disposed on the left side (as shown) of first TE device 360. Furthermore, first fin 372 is disposed on the right side (as shown) of first TE device 360. Such a configuration maximizes the temperature difference across first TE device 360 (i.e., hot on the side of first fin 372 and cool on the side of first cooling channel 390), thereby maximizing energy production from first TE device 360. Furthermore, in some embodiments the cooling channel may be sandwiched between two or more TE devices (e.g., second cooling channel 392) to optimize spatial constraints of power generation and cooling system 300.

In some embodiments, the multiple TE devices may be connected in a series configuration, a parallel configuration, or a combination of series and parallel configurations. For example, as depicted in FIG. 3, first, second, third, fourth, fifth, and sixth TE devices 360, 361, 362, 363, 364, and 365, are all connected in series, with the output directed to power connection 380. In some embodiments, there may be multiple groupings of TE devices, each group connected to one another in a parallel configuration while internally connected within the group in a series configuration. For example, a first group of TE devices connected to each other in a series configuration may be connected to a second group of TE devices also connected to each other in a series configuration, the first group of TE devices connected to the second group of TE devices via a parallel configuration. Said another way, the first group is in a series configuration, the second group is in a series configuration, and the first group is connected to the second group in a parallel configuration. It is contemplated that embodiments disclosed herein may include any number of groups of TE devices connected to each other, either in series or in parallel. Similar to power connections 180 and 280 depicted in FIGS. 1 and 2, power connection 380 may be connected to a battery (e.g., battery 120) or power supply (e.g., power supply 130) as part of a laser device (e.g., laser device 100).

The heat sink 370 depicted in FIG. 3 aids in release of heat via the physical structure of heat sink 370. For example, as is known by one or ordinary skill in the art, increasing the surface area of heat sink 370 aids in more rapid release of heat from the heat sink 370, thereby aiding in heat transfer from the photodiode array 340. Accordingly, in some embodiments heat sink 370 may comprise other physical forms that additionally increase surface area and thus increase heat transfer. For example, heat sink 370 may be pleated or any other shape that increases surface area of heat sink 370 and enhances heat transfer from photodiode array 340. Furthermore, in some embodiments power generation and cooling system 300 includes an additional cooling element, such as a fan, to aid in the heat transfer from heat sink 370.

It is to be understood that, while some embodiments are described above with relationship to FIGS. 1-3, components from these embodiments may be combined or separated without departing from the scope hereof. For example, heat sink 370 and associated TE devices 360, 361, 362, 363, 364, 365, depicted in FIG. 3 may be placed on a side of photodiode array 140 depicted in FIG. 1.

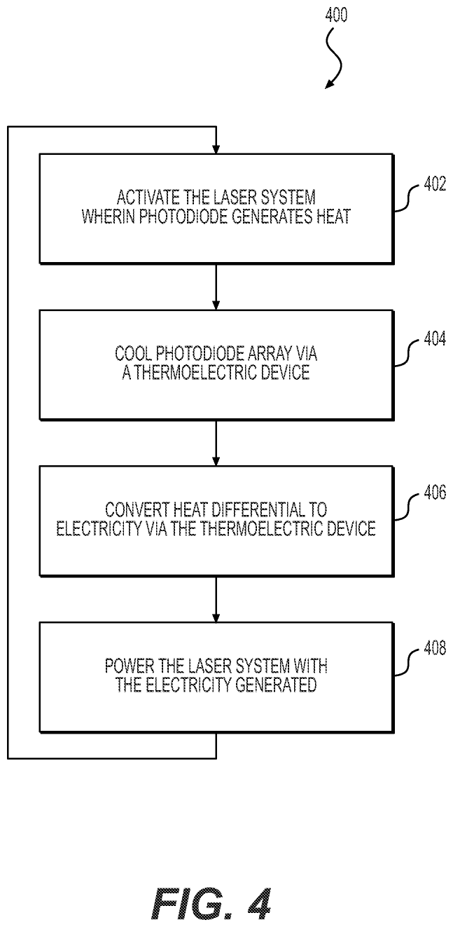

Now turning to FIG. 4 a method for cooling and powering a laser device is depicted and referred to generally by reference numeral 400. At step 402, a laser device (e.g., laser device 100) comprising one or more photodiode arrays (e.g., photodiode array 140) is activated. In this embodiment, activation of the laser device comprises powering laser fibers (e.g., laser fibers 150) by means of activating the photodiode array. In embodiments, the photodiode array emits heat due to activation of the laser device. It should be understood that the laser device may require a period of time before being activated a second time due to excessive heating of the photodiode array. As such, the laser device may only be activated a second time once the photodiode array has cooled to a predetermined low temperature threshold.

At step 404 a TE device cools the photodiode array. Here, the TE device (e.g., TE device 160) receives heat radiated from the photodiode array. This process effectively transfers heat away from the photodiode array, thereby decreasing the time required for the photodiode array to cool to the predetermined low temperature threshold. Absorption of heat by the TE device may be direct (e.g., as depicted in FIG. 1), or indirect such as through a microchannel plate or heat sink (e.g., as depicted in FIGS. 2-3). Furthermore, there may be one or more TE devices acting at step 404 to cool the photodiode array.

At step 406 the TE device converts the difference in temperature from one side of the TE device and the other side of the TE device to electrical energy. Here, a first side of the TE device (e.g., side 162) disposed adjacent to the photodiode array experiences a significant increase in temperature due to activation of the laser device in step 402. The second side (e.g., side 164) of the TE device, disposed a distance away from the photodiode array, experiences a lower temperature than the first side of the TE device. This difference in temperature allows for generation of electricity by means of the Seebeck effect. Embodiments of step 406 may include cooling the second side of the TE device, for example, by using cooling channels (e.g., first cooling channel 170) or microchannel plates (e.g., second microchannel plate 292).

At step 408 the TE device powers the laser device with electricity generated in step 406. Here, to improve efficiency of the laser device, the TE device directly charges one or more of a battery (e.g., battery 120) and/or a power supply (e.g., power supply 130) of the laser device.

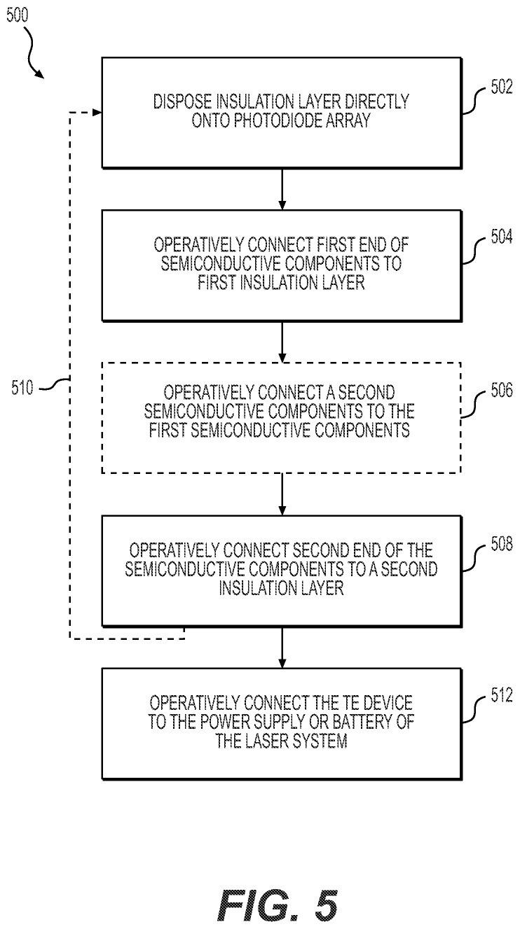

Referring now to FIG. 5 a process for manufacturing a TE device mechanically coupled to a photodiode array is depicted and referred to generally by reference numeral 500. At step 502, a first insulation layer is disposed onto a photodiode array, microchannel plate, or heat sink as discussed above with reference to FIGS. 1-3. The first insulation layer may comprise one or more of ceramic, plastic, or rubber. In one embodiment, the first insulation layer may completely coat a side of the photodiode array. In one embodiment, the first insulation layer may completely encase the photodiode array in a tubular fashion.

At step 504, a first end of a plurality of semiconductive components are operatively connected to the first insulation layer and electrically interconnected. Here, the first end of the semiconductive components is operatively connected to the first insulation layer by means in which a metal contact is made between the first end of the semiconductive components and the first insulation layer. Furthermore, this metal contact serves to electrically interconnect the plurality of semiconductive components. In one embodiment, the first end of the semiconductive components is operatively connected by polishing of the first end of the semiconductive components to the first insulation layer. In one embodiment, the first end of the semiconductive components is operatively connected by soldering the first end of the semiconductive components to the first insulation layer.

At optional step 506, a second layer of a plurality of semiconductive components are operatively connected to the first layer of semiconductive components disposed in step 504. Here, the semiconductive components are arranged in a segmented configuration, as described above.

At step 508, a second end of the plurality of semiconductive components are operatively connected to a second insulation layer and electrically interconnected. Here, the second end of the semiconductive components is operatively connected to the second insulation layer by means in which a metal contact is made between the second end of the semiconductive components and the second insulation layer. Furthermore, this metal contact serves to electrically interconnect the plurality of semiconductive components. In one embodiment, the second end of the semiconductive components is operatively connected by soldering the second end of the semiconductive components to the second insulation layer.

At optional step 510, the manufacturing process 500 feeds back into step 502. Here, an option to assemble TE devices in a cascaded configuration is detailed, as described above. In optional step 510, the manufacturing process 500 proceeds by stacking TE devices on top of each other. In greater detail, a third insulation layer is disposed on the second insulation layer. Said third insulation layer may serve to operatively connect a second plurality of semiconductive components, as discussed in step 504. Furthermore, optional step 510 may be used to dispose multiple TE devices on a portion of the photodiode array, microchannel plate, or heat sink as discussed above with reference to FIGS. 1-3.

At step 512, the TE device is operatively connected to a battery or power supply of a laser device. Here, an electrical connection is made between one or more TE devices disposed adjacent to the photodiode array and a battery and/or power supply that power a laser device. This electrical connection may transfer electricity generated by the TE device to the laser device, thereby effectively retaining energy within the laser device by capturing the energy inherently produced within a laser device in the form of heat and converting it back to electrical energy.

Although the invention has been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A power generation and cooling system for a laser device, the system comprising:
one or more thermoelectric devices, each defining a first side and a second side,
wherein the first side engages a photodiode array of the laser device and configured to receive heat therefrom,
wherein the second side engages a cooling element of the laser device;
a plurality of thermoelectric elements disposed between the first side and the second side; and
a power connection,
wherein the power connection electrically connects the one or more thermoelectric devices and the laser device.

2. The system of claim 1, wherein the power connection electrically connects the one or more thermoelectric devices to a battery of the laser device and configured to charge the battery.

3. The system of claim 1, further comprising a thermally conductive material disposed between the first side and the photodiode array.

4. The system of claim 1, wherein the cooling element comprises an outer portion defining a cavity, wherein the cavity houses a cooling liquid.

5. The system of claim 4, further comprising an additional cooling element disposed on an opposing side of the photodiode array from the one or more thermoelectric devices.

6. The system of claim 1, further comprising a first microchannel plate disposed between the first side of the one or more thermoelectric devices and the photodiode array, and wherein the cooling element comprises a second microchannel plate.

7. The system of claim 6, further comprising a controller configured to command one or more valves of the first microchannel plate and the second microchannel plate, wherein the one or more valves are configured to allow flow of a coolant thereby when in an open configuration.

8. The system of claim 7, further comprising a temperature probe disposed at the photodiode array and communicatively coupled to the controller, the temperature probe configured to relay thermal data to the controller.

9. A power generation and cooling system for a laser device, the system comprising:
at least one heat sink engaging a photodiode array of the laser device;
one or more thermoelectric devices, each defining a first side and a second side having a plurality of thermoelectric elements disposed therebetween,
wherein the first side of each of the one or more thermoelectric devices engages the at least one heat sink and receives heat therefrom; and
a power connection electrically coupling the one or more thermoelectric devices to the laser device.

10. The system of claim 9, wherein each heat sink comprises a plurality of fins extending outwardly therefrom, and wherein the first side of each of the one or more thermoelectric devices engages a fin.

11. The system of claim 10, further comprising one or more cooling channels disposed adjacent to the second side of each of the one or more thermoelectric devices.

12. The system of claim 11, wherein the one or more thermoelectric devices comprises at least two thermoelectric devices electrically coupled in a series configuration to the power connection.

13. The system of claim 12, wherein the power connection is electrically coupled to a battery of the laser device and configured to charge the battery.

14. The system of claim 13, further comprising a thermal insulator encompassing the photodiode array, the at least one heat sink, and the one or more thermoelectric devices.

15. A method for cooling and powering a laser device, the method comprising:
activating the laser device, wherein activation of the laser device generates heat at a photodiode array of the laser device;
receiving the heat generated by the photodiode array at a first side of a thermoelectric device;
generating electricity at the thermoelectric device via the heat received at the first side; and
powering the laser device via the electricity generated from the thermoelectric device.

16. The method of claim 15, further comprising:
cooling a second side of the thermoelectric device via a cooling channel disposed adjacent to the second side.

17. The method of claim 15, further comprising:
transferring the heat generated at the photodiode array to a heat sink prior to receiving the heat generated by the photodiode array at the first side of the thermoelectric device, the heat being received at the first side from the heat sink.

18. The method of claim 15, wherein powering the laser device comprises charging a battery of the laser device.

19. The method of claim 15, further comprising:
receiving information indicative of a temperature of the photodiode array at a controller via a temperature probe;
determining the temperature is above a predetermined high temperature threshold; and
commanding open a plurality of valves of a microchannel plate, the microchannel plate being disposed at the photodiode array and configured to cool the photodiode array.

20. The method of claim 19, further comprising:
following commanding open the plurality of valves of the microchannel plate, receiving information indicative of the temperature of the photodiode array at the controller via the temperature probe;
determining the temperature of the photodiode array is below a predetermined low temperature threshold; and
commanding closing of the plurality of valves of the microchannel plate.
